(19) United States
(12) Patent Application Publication
(10) Pub. No.: US 2024/0332128 A1
(43) Pub. Date: Oct. 3, 2024

(54) EMBEDDED COOLING SYSTEMS FOR DEVICE PACKAGES AND METHODS OF COOLING PACKAGED DEVICES

(71) Applicant: Adeia Semiconductor Bonding Technologies Inc., San Jose, CA (US)

(72) Inventors: Cyprian Emeka Uzoh, San Jose, CA (US); Belgacem Haba, Saratoga, CA (US); Rajesh Katkar, Milpitas, CA (US)

(21) Appl. No.: 18/129,567

(22) Filed: Mar. 31, 2023

(51) Int. Cl. H01L 23/46; H01L 23/367; H01L 23/433

(52) U.S. Cl. CPC H01L 23/46; H01L 23/367; H01L 23/433

(57) ABSTRACT

Embodiments herein provide for device packages comprising an integrated cooling assembly and methods of cooling packaged devices. The integrated cooling assembly comprising a semiconductor device, a manifold attached to the semiconductor device, and a sonic transducer attached to the manifold. The manifold comprises a top portion and a waveguide extending downwardly from the top portion. The sonic transducer is attached to the top portion. The top portion, the waveguide, and a backside of the semiconductor device collectively define a coolant chamber volume therebetween.

### FIELD

The present disclosure relates to advanced packaging for microelectronic devices, and in particular, embedded cooling systems for device packages and methods of cooling packaged devices.

### BACKGROUND

Energy consumption poses a critical challenge for the future of large-scale computing as the world's computing energy requirements are rising at a rate that most would consider unsustainable. Some models predict that the information and communications technology (ICT) ecosystem could exceed 20% of global electricity use by 2030, with direct electrical consumption by large-scale computing centers accounting for more than one-third of that energy usage. Cooling costs make up a significant portion of computing center energy requirements as even small increases in operating temperatures can negatively impact the performance of microprocessors, memory devices, and other electronic components.

Thermal dissipation in high-power density chips is also a critical challenge as improvements in chip performance, e.g., through increased gate density and multi-core microprocessors, have resulted in increased power density and a corresponding increase in thermal flux that contributes to elevated chip temperatures. These elevated temperatures are undesirable as they can degrade the chip's operating performance, efficiency, and reliability. Accordingly, there exists a need in the art for improved performance of cooling systems.

### SUMMARY

One general aspect includes a device package comprising an integrated cooling assembly. The integrated cooling assembly comprising a semiconductor device, a manifold attached to the semiconductor device, and a sonic transducer attached to the manifold. The manifold comprises a top portion and a waveguide extending downwardly from the top portion. The sonic transducer is attached to the top portion. The top portion, the waveguide, and a backside of the semiconductor device collectively define a coolant chamber volume therebetween.

In some embodiments, the top portion of the manifold may comprise a package cover. The package cover may have an inlet opening and an outlet opening disposed therethrough. The coolant chamber volume may be in fluid communication with the inlet opening and the outlet opening.

In some embodiments, the sonic transducer may be disposed in the coolant chamber volume.

In some embodiments, the top portion of the manifold may comprise a first side facing towards the semiconductor device and a second side opposite the first side. The sonic transducer may be attached to the second side.

In some embodiments, sidewalls defining one or more openings in the top portion of the manifold comprise helicoid ribs.

In some embodiments, the sonic transducer may comprise plural elements each positioned to transmit sonic energy towards the semiconductor device through the coolant chamber volume.

Another general aspect includes a device package comprising an integrated cooling assembly. The integrated cooling assembly comprises a semiconductor device and a manifold attached to the semiconductor device. An upper portion of the manifold may be spaced apart from the semiconductor device to collectively define a coolant chamber volume therebetween. The manifold may comprise a shower plate between the upper portion of the manifold and the semiconductor device. The shower plate may define an upper fluid volume with the upper portion of the manifold and a lower fluid volume with the semiconductor device. The lower fluid volume may be in fluid communication with the upper fluid volume through a plurality of openings in the shower plate. In some embodiments, one or more sidewalls defining the plurality of openings may comprise helicoid ribs positioned to generate a vortex in a fluid flowing from the upper fluid volume to the lower fluid volume.

Another general aspect includes a device package comprising an integrated cooling assembly. The integrated cooling assembly comprises a semiconductor device, a manifold attached to the semiconductor device, a coolant line, and a sonic transducer. The manifold comprises a top portion and a waveguide extending downwardly from the top portion. The top portion, the waveguide, and a backside of the semiconductor device collectively define a coolant chamber volume therebetween. The coolant line is positioned outside the coolant chamber volume and connected to the top portion of the manifold. The sonic transducer is connected along the coolant line.

Another general aspect includes a method of cooling a packaged semiconductor device. The method comprises generating, by a sonic transducer, sonic energy. The method further comprises transmitting, by the sonic transducer, the sonic energy through a fluid towards a backside of the packaged semiconductor device.

### BRIEF DESCRIPTION OF THE DRAWINGS

The above and other objects and advantages of the disclosure will be apparent upon consideration of the following detailed description, taken in conjunction with the accompanying drawings, in which:

FIG. 1 is a schematic plan view of an example of a system panel, in accordance with embodiments of the present disclosure;

FIG. 2 is a schematic partial sectional side view of a portion of the system panel of FIG. 1;

FIG. 3 is a schematic sectional view of an example device package, in accordance with embodiments of the present disclosure, that may be used with the system panel;

FIG. 4 is a schematic sectional view of an example integrated cooling assembly, according to some embodiments, that may be used with the device package;

FIG. 5 is a schematic sectional view of another example integrated cooling assembly, according to some embodiments, that may be used with the device package;

FIG. 6 is a schematic view of shower plates, according to some embodiments, that may be used with the device package;

FIG. 7 is a schematic sectional view of another example integrated cooling assembly, according to some embodiments, that may be used with the device package;

FIG. 8 is a schematic sectional view of another example integrated cooling assembly, according to some embodiments, that may be used with the device package;

FIG. 9 is a schematic sectional view of another example integrated cooling assembly, according to some embodiments, that may be used with the device package;

FIG. 10 is a schematic sectional view of another example device package, in accordance with embodiments of the present disclosure, that may be used with the system panel;

FIG. 11 is a schematic sectional view of another example device package, in accordance with embodiments of the present disclosure, that may be used with the system panel;

FIG. 12 is a schematic sectional view of another example device package, in accordance with embodiments of the present disclosure, that may be used with the system panel;

FIG. 13 is a schematic isometric view of helicoidal ribs, according to some embodiments, that may be used with example integrated cooling assemblies; and

FIG. 14 shows a method that can be used to cool a packaged semiconductor device.

The figures herein depict various embodiments of the disclosed for purposes of illustration only. It will be appreciated that additional or alternative structures, assemblies, systems, and methods may be implemented within the principles set out by the present disclosure.

### DETAILED DESCRIPTION

As used herein, the term “substrate” means and includes any workpiece, wafer, or article that provides a base material or supporting surface from which or upon which components, elements, devices, assemblies, modules, systems, or features of the heat-generating devices, packaging components, and cooling assembly components described herein may be formed. The term substrate also includes “semiconductor substrates” that provide a supporting material upon which elements of a semiconductor device are fabricated or attached, and any material layers, features, and/or electronic devices formed thereon, therein, or therethrough.

As described below, the semiconductor substrates herein generally have a “device side,” e.g., the side on which semiconductor device elements are fabricated, such as transistors, resistors, and capacitors, and a “backside” that is opposite the device side. The term “active side” should be understood to include a surface of the device side of the substrate and may include the device side surface of the semiconductor substrate and/or a surface of any material layer, device element, or feature formed thereon or extending outwardly therefrom, and/or any openings formed therein. Thus, it should be understood that the material(s) that form the active side may change depending on the stage of device fabrication and assembly. Similarly, the term “non-active side” (opposite the active side) includes the non-active side of the substrate at any stage of device fabrication, including the surfaces of any material layer, any feature formed thereon, or extending outwardly therefrom, and/or any openings formed therein. Thus, the terms “active side” or “non-active side” may include the respective surfaces of the semiconductor substrate at the beginning of device fabrication and any surfaces formed during material removal, e.g., after substrate thinning operations. Depending on the stage of device fabrication or assembly, the terms “active” and “non-active sides” are also used to describe surfaces of material layers or features formed on, in, or through the semiconductor substrate, whether or not the material layers or features are ultimately present in the fabricated or assembled device.

Spatially relative terms are used herein to describe the relationships between elements, such as the relationships between substrates, heat-generating devices, cooling assembly components, device packaging components, and other features described below. Unless the relationship is otherwise defined, terms such as “above,” “over,” “upper,” “upwardly,” “outwardly,” “on,” “below,” “under,” “beneath,” “lower,” and the like are generally made with reference to the X, Y, and Z directions set forth by X, Y and Z axis in the drawings. Thus, it should be understood that the spatially relative terms used herein are intended to encompass different orientations of the substrate and, unless otherwise noted, are not limited by the direction of gravity. Unless the relationship is otherwise defined, terms describing the relationships between elements such as “disposed on,” “embedded in,” “coupled to,” “connected by,” “attached to,” “bonded to,” either alone or in combination with a spatially relevant term include both relationships with intervening elements and direct relationships where there are no intervening elements. Furthermore, the terms “horizontal” and “vertical” are generally made with reference to the X and Z directions set forth in the drawings, respectively.

Unless otherwise noted, the terms “cooling assembly” and “integrated cooling assembly” generally refers to a semiconductor device and a manifold attached to the semiconductor device. Typically, the manifold is formed with recessed surfaces that define a fluid cavity (e.g., a coolant chamber volume) between the manifold and the semiconductor device. The manifold may be attached to the semiconductor device by use of a compliant adhesive layer or by direct dielectric or hybrid bonding. For example, the manifold may include material layers and or metal features which facilitate direct dielectric or hybrid bonding with the semiconductor device. Beneficially, the backside of the semiconductor device is directly exposed to coolant fluids flowing through the integrated cooling assembly, thus providing for direct heat transfer therebetween. Unless otherwise noted, the integrated cooling assemblies described herein may be used with any desired fluid, e.g., liquid, gas, and/or vapor-phase coolants, such as water and/or glycol, for example. In some embodiments, the coolant may contain additives to enhance the conductivity of the cooling fluid within the integrated cooling assemblies. The additives may comprise for example, nano-particles of carbon nanotube, nano-particles of graphene, nano-particles of metal oxides. The concentration of these nano-particles may be less than 1%, less than 0.2% and still less than 0.05%. The cooling fluids may also contain small amount of glycol or glycols (e.g. propylene glycol, ethylene glycol etc.) to reduce frictional shear stress and drag coefficient in the cooling fluid within the integrated cooling assembly.

As described below, the coolant fluid may be used to control the temperature of semiconductor devices. The fluid flowing across the surface of the semiconductor device absorbs heat and conducts heat away from the device. Unfortunately, as the coolant fluid flows across the semiconductor device surface, a slow moving fluid boundary layer may form adjacent to the surface. Such fluid boundary layers are undesirable as they reduce convective heat transfer between the device and the coolant fluid. Thus, for some high-powered devices, heat cannot be conducted away quickly enough to allow the device to run at optimal power, thus reducing the devices' energy efficiency.

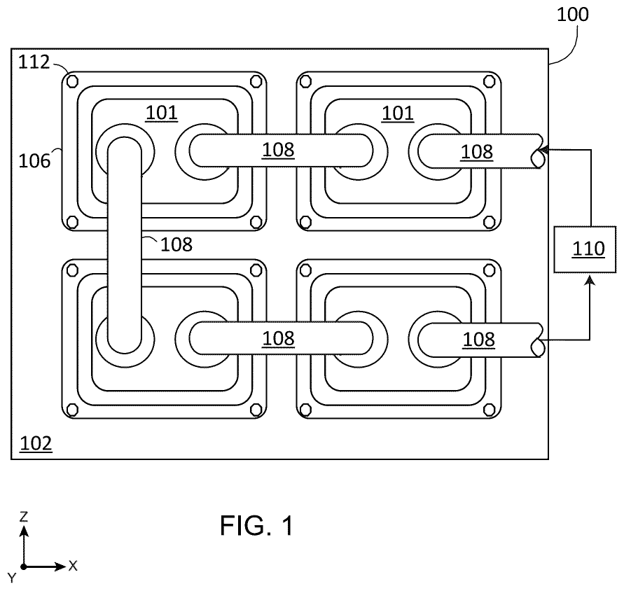

FIG. 1 is a schematic plan view of an example of a system panel 100, in accordance with embodiments of the present disclosure. Here, the system panel 100 includes a printed circuit board (PCB), PCB 102, a plurality of device packages 101 mounted to the PCB 102, and a plurality of coolant lines 108 fluidly coupling each of the device packages 101 and to a coolant source 110. It is contemplated that coolant may be delivered to each of the device packages 101 in any desired fluid phase, e.g., liquid, vapor, gas, or combinations thereof and may flow out from the device package 101 in the same phase or a different phase. In some embodiments, the coolant is delivered to the device package 101 and returned therefrom as a liquid and the coolant source 110 may comprise a heat exchanger or chiller to maintain the coolant at a desired temperature. In other embodiments, the coolant may be delivered to the device packages 101 as a liquid, vaporized to a liquid within the device package, and returned to the coolant source 110 as a vapor. In those embodiments, the device packages 101 may be fluidly coupled to the coolant source 110 in parallel and the coolant source 110 may include or further include a compressor (not shown) for condensing the received vapor to a liquid form.

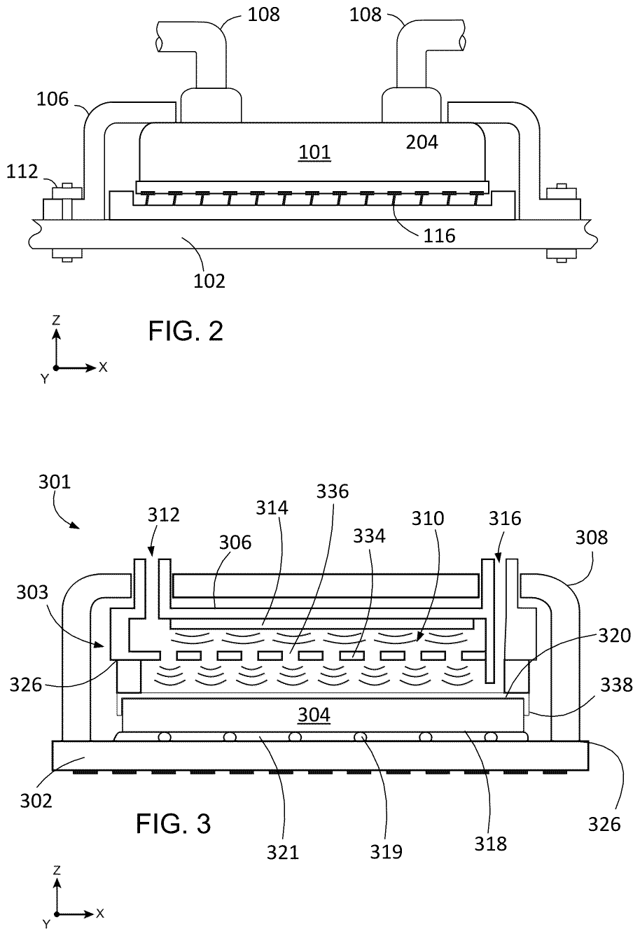

FIG. 2 is a schematic partial sectional side view of a portion of the system panel 100 of FIG. 1. As shown, each device package 101 is disposed in a socket 204 of the PCB 102 and connected thereto using a plurality of pins 116, or by other suitable connection methods, such as solder bumps (not shown). The device package 101 may be seated in the socket 204 and secured to the PCB 102 using a mounting frame 106 and a plurality of fasteners 112, e.g., compression screws, collectively configured to exert a relatively uniform downward force on the upward facing edges of the device package 101. The uniform downward force ensures proper pin contact between the device package 101 and the socket 204.

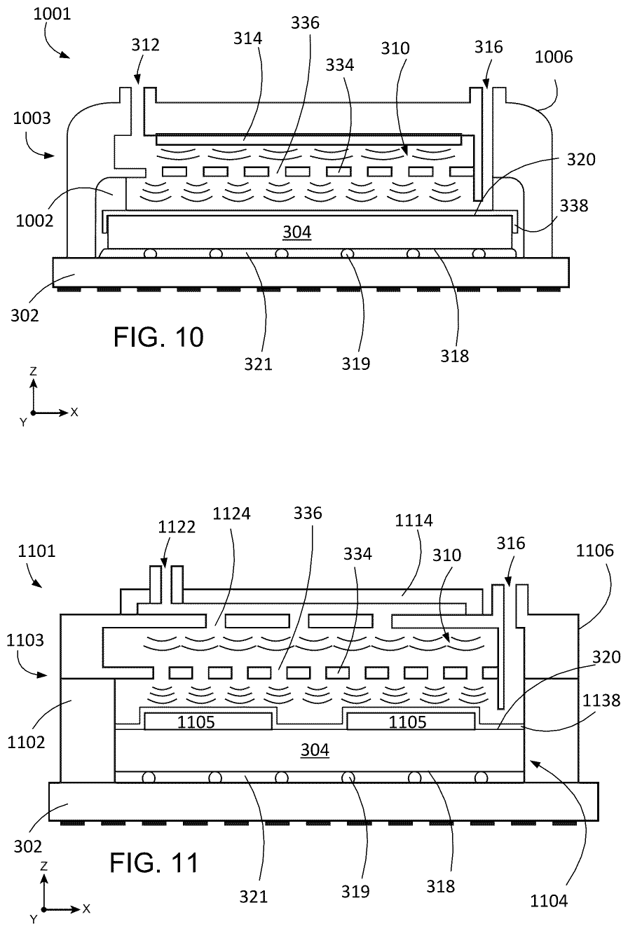

FIG. 3 is a schematic sectional view of an example device package 301, in accordance with embodiments of the present disclosure. As shown, the device package 301 includes a package substrate 302, an integrated cooling assembly 303 disposed on the package substrate 302, and a package cover 308. The package cover 308 may be disposed on a peripheral portion of the package substrate 302 and shaped to extend over the integrated cooling assembly 303 so that the integrated cooling assembly is disposed between the package substrate 302 and the package cover 308. Here, portions of the manifold 306 extend upwardly through openings in the package cover 308 to facilitate attachment of coolant delivery lines. In some embodiments, the coolant delivery lines may be attached directly to the package cover, such as described in relation to FIG. 10.

Generally, the package substrate 302 comprises a rigid material, such as an epoxy or resin-based laminate, that supports the integrated cooling assembly 303 and the package cover 308. The package substrate 302 may include conductive features disposed in or on the rigid material that electrically couple the integrated cooling assembly 303 to a system panel, such as the PCB 102.

Here, the integrated cooling assembly 303 comprises a semiconductor device 304, a manifold 306 attached to the semiconductor device 304, and a megasonic transducer 314 attached to the manifold 306. Without intending to be bound by theory, it is believed that megasonic transducers can be safely used without causing damage to the device package as megasonic frequencies are outside of the resonant frequency of typical device components. Nonetheless, it will be understood that other types of sonic transducers may be used with the integrated cooling assemblies of the present disclosure when other sonic frequencies are desired, e.g., ultrasonic frequencies as further described below. However, for consistency, the term “megasonic transducer” will be used from hereon.

Here, the semiconductor device 304 comprises an active side 318 that includes device components, e.g., transistors, resistors, and capacitors, formed thereon or therein, and a non-active side, here a backside 320 of the semiconductor device 304, opposite the active side 318. In some embodiments, the semiconductor device 304 comprises a high-power microprocessor or graphics processor capable of operating in the region of 150 Watts and beyond, such as a device suitable for use in applications such as cloud storage. As shown, the active side 318 is positioned adjacent to and facing towards the package substrate 302. The active side 318 may be electrically connected to the package substrate 302 by use of conductive bumps 319, which are encapsulated by a first underfill layer 321 disposed between the semiconductor device 304 and the package substrate 302. The first underfill layer 321 may comprise a cured polymer resin or epoxy, which provides mechanical support to the conductive bumps 319 and protects against thermal fatigue. The polymer resin may comprise particulate composite material, small particulates of silicon, silicon oxide amongst other having been compounded into the resin to reduce the coefficient of thermal expansion (CTE) of the cure polymer resin.

In some embodiments, the backside 320 of the semiconductor device 304 comprises a corrosion protective layer 338. The corrosion protective layer 338 may be a continuous layer disposed across the entire backside 320 of the semiconductor device 304, such that the manifold 306 is attached thereto. Furthermore, the continuous corrosion protective layer may extend to side portions of the semiconductor device 304, as illustrated. Beneficially, the corrosion protective layer 338 provides a corrosion resistant barrier layer, thus preventing undesired corrosion of the semiconductor device 304 (e.g., the semiconductor substrate material which might otherwise be in direct contact with fluid flowing through the coolant chamber volume 310).

The manifold 306 comprises a top portion and a waveguide extending downwardly from the top portion towards the backside 320 of the semiconductor device 304. The top portion of the manifold 306 comprises a first side facing towards the semiconductor device 304 and a second side opposite the first side. The second side faces the package cover 308 (e.g., the second side is external to a coolant chamber volume 310 and faces away from the semiconductor device 304. When the manifold 306 is attached to the semiconductor device 304, a coolant chamber volume 310 is formed between the top portion, the waveguide, and the backside 320 of the semiconductor device 304. The coolant chamber volume 310 is in fluid communication with an inlet opening 312 of the manifold 306 and an outlet opening 316 of the manifold 306. The fluid connection facilitates a flow of fluid (e.g., coolant fluid) into the coolant chamber volume 310 through the inlet opening 312, across the surface of the backside 320 of the semiconductor device 304, and out of the coolant chamber volume 310 through the outlet opening 316. Here, cool fluid enters the coolant chamber volume 310 and, as the cool fluid flows across the backside 320 of the semiconductor device 304, heat is transferred to the fluid thus increasing the fluid temperature. Heated fluid (e.g., fluid to which heat has been transferred from the semiconductor device 304) exits the coolant chamber volume 310 through the outlet opening 316. The interface between the manifold 306 and the semiconductor device 304 may be fluid resistant such that fluid is retained in the coolant chamber volume 310. That is, the only means by which fluid may enter and exit the coolant chamber volume 310 may be via the inlet opening 312 and the outlet opening 316. It will be understood that the inlet opening 312 and the outlet opening 316 may be reversed in order that fluid may flow through the coolant chamber volume 310 in the opposite direction to that described above.

As illustrated in FIG. 3, the manifold 306 may comprise an outlet conduit connected to the outlet opening 316 which extends into the coolant chamber volume 310 towards the backside 320 of the semiconductor device 304. A distance between the backside 320 of the semiconductor device 304 and an opening of the outlet conduit may be less than the distance between the top portion of the manifold and the backside 320 of the semiconductor device 304. This difference in distances provides a means for controlling the flow of fluid across the backside 320 of the semiconductor device 304 as fluid flows through the coolant chamber volume 310. For example, fluid may only enter the outlet conduit after having first flowed within a predetermined distance from the backside 320 of the semiconductor device 304.

The manifold 306 may be formed of any suitable material that has sufficient structural strength to withstand the desired pressures of the coolant flowed into the chamber volume. For example, the manifold 306 may be formed of a material selected from a group comprising polymers, metals, ceramics, or composites thereof. In some embodiments, the manifold may formed of stainless steel (e.g., from a stainless steel metal sheet) or a sapphire plate. In some embodiments, the manifold 306 may be formed of a material having a substantially different coefficient of thermal expansion (CTE) from the semiconductor device, e.g., a CTE mismatched material. In such embodiments, the manifold 306 may be attached to the semiconductor device 304 by a compliant adhesive layer 326 or a molding material that absorbs the difference in expansion between the manifold and the semiconductor device across repeated thermal cycles.

In some embodiments, a relatively thick layer of molding material may be disposed between the manifold 306 and the semiconductor device 304 in order to increase the distance between the top portion of the manifold 306 and the semiconductor device 304, which increases the volume of the coolant chamber volume 310. In such an arrangement, the molding material forms coolant chamber walls, the manifold 306 form a coolant chamber cap, and the backside 320 of the semiconductor device 304 forms a bottom of the coolant chamber volume 310 and is in thermal contact with fluid flowing therethrough. The inlet opening 312 and the outlet opening 316 of the manifold 306 may be in fluid communication with inlet and outlet openings of the package cover 308.

As will be discussed in more details below, the megasonic transducer 314 may be attached to the manifold 306 in a variety of configurations and arrangement, and it is contemplated that each configuration may be incorporated into the integrated cooling assembly 303 without further recitation. As shown, the megasonic transducer 314 is attached to an inner surface of the manifold 306 and has a substantially horizontal orientation, such that the megasonic transducer extends the X-axis direction.

As shown, the megasonic transducer 314 is attached to the first side of the manifold 306, such that the megasonic transducer 314 is disposed inside the coolant chamber volume 310 opposite the backside 320 of the semiconductor device 304. Beneficially, by providing the megasonic transducer 314 inside the coolant chamber volume 310, the megasonic transducer 314 itself may be cooled by fluid flowing through the coolant chamber volume 310, which ensures an optimum operating temperature of the megasonic transducer 314.

The megasonic transducer 314 may comprise an actuator that converts an electrical input signal, received from control circuitry, into rotary and/or linear physical motion thus generating megasonic vibrations. Here, the megasonic vibrations are transmitted towards the backside of the semiconductor device 304 in the form of sonic energy at a frequency from about 200 kilohertz (kHz) to about 5 megahertz (MHz). The waveguide of the manifold 306 may direct the megasonic vibrations, in the form of sonic energy, towards the backside 320 of the semiconductor device 304 through fluid flowing through the coolant chamber volume 310. In embodiments where the megasonic transducer 314 is disposed inside the coolant chamber volume 310, sonic energy is transmitted directly through the fluid without obstruction by the top portion of the manifold, which improves the efficiency of energy transfer.

In some embodiments, the megasonic transducer 314 may be wirelessly coupled to control circuitry thus providing a means for wirelessly controlling the generation of megasonic vibrations in the device package 301 to provide on demand megasonic action.

Example transducers which may be used as the megasonic transducer according to embodiments of the present disclosure include: magnetostrictive transducers and piezoelectric transducers. Furthermore, such transducers may be implemented as microelectromechanical system (MEMS) devices.

Beneficially, the megasonic vibrations generated by the megasonic transducer 314 introduce turbulence into the fluid flowing through the coolant chamber volume 310. Turbulence introduced by the megasonic transducer 314 increases convective heat transfer from the semiconductor device 304 to the fluid by thinning the stagnant fluid boundary layer adjacent to the backside 320 of the semiconductor device 304. Furthermore, turbulence introduced by the megasonic transducer 314 reduces the occurrence of hot spots in the semiconductor device 304 by encouraging movement of the fluid across the entire backside 320 of the semiconductor device 304. The improved heat transfer effects provided by the megasonic transducer 314 facilitate an increased power density of the device package 301 in the range of about 0.5 to 10 Watts/cm² (in terms of surface thermal extraction). It will be understood that increased power density may alternatively be represented using typical power density units in Watts/cm³ (e.g. 2 to 20 Watts/cm³).

The manifold 306 may be thermally coupled to the semiconductor device 304 using a compliant adhesive layer 326, such as a thermally conductive paste, grease, adhesive material, or other thermally conductive material, such as a fusible metal alloy and the like, e.g., solder, or combinations thereof. The compliant adhesive layer 326 may be disposed directly between sidewalls of the manifold and the semiconductor device 304. In embodiments comprising molding material, the compliant adhesive layer 326 may be disposed between the molding material and the semiconductor device 304 and/or between the molding material and the sidewalls of the manifold.

As shown in FIG. 3, the manifold 306 may comprise a shower plate 334 disposed inside the coolant chamber volume 310 between the top portion of the manifold and the semiconductor device 304. The shower plate 334 may extend between the sidewalls of the manifold thus defining an upper fluid volume with the top portion (e.g., upper portion) of the manifold and a lower fluid volume with the semiconductor device 304. That is, the upper fluid volume is disposed above the shower plate 334 and the lower fluid volume is disposed below the shower plate 334. The distance between the semiconductor device 304 and the shower plate 334 may be adjusted compared to the distance between the top portion of the manifold and the shower plate 334, by moving the position of the shower plate 334 up or down within the coolant chamber volume 310, to adjust the relative volumes of the upper fluid volume and the lower fluid volume.

Here, the lower fluid volume is in fluid communication with the upper fluid volume through a plurality of openings 336 in the shower plate 334 such that fluid flows between the upper fluid volume and the lower fluid volume. An example flow path of fluid through the upper fluid volume and the lower fluid volume may be as follows:
1. fluid enters the upper fluid volume through the inlet opening 312;
2. fluid flows from the upper fluid volume to the lower fluid volume through the plurality of openings 336 of the shower plate 334;
3. fluid flows across the backside of the semiconductor device 320 and absorbs heat generated by the semiconductor device 304;
4a. in embodiments where the manifold 306 comprises the outlet conduit, the fluid flows into the opening of the outlet conduit and exits the coolant chamber volume 310 via the outlet opening 316;
4b. in embodiments where the manifold 306 does not comprise the outlet conduit, the fluid flows through the lower fluid volume to the upper fluid volume through the plurality of openings 336 and exits the coolant chamber volume 310 via the outlet opening 316.

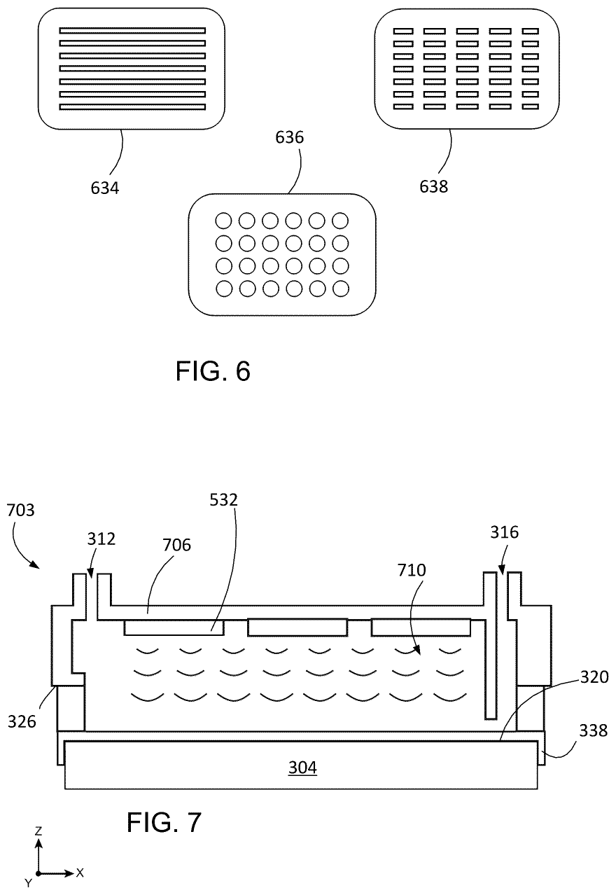

The plurality of openings 336 may be arranged in rows and/or columns of rectangular, circular or square shaped openings, as illustrated in FIG. 6. In particular, the top left shower plate 634 of FIG. 6 illustrates a shower plate comprising seven rows of rectangular openings. The bottom shower plate 636 of FIG. 6 illustrates a shower plate comprising four rows and six columns of circular openings. The top right shower plate 638 of FIG. 6 illustrates a shower plate comprising seven rows and five columns of rectangular openings. It will be understood that plural shower plates may be stacked inside the coolant chamber volume 310 in order to provide additional control over turbulence introduced into fluid as the fluid passes through each stacked shower plate.

Each opening of the plurality of openings 336 may be defined by one or more sidewalls. In embodiments where the plurality of openings 336 are circular, each opening is defined by a cylindrical sidewall through which fluid may pass. In other embodiments where the plurality of openings 336 are rectangular, each opening is defined by four rectangular sidewalls.

The one or more sidewalls may comprise helicoid ribs, as illustrated in FIG. 13. The helicoid ribs 1326 illustrated in FIG. 13 generate a vortex in fluid flowing from the upper fluid volume to the lower fluid volume. That is, as fluid flows through the plurality of openings 336, the helicoid ribs guide the fluid in a downward circular motion thus generating a vortex in the fluid. The fluid vortex induces massive stirring on the backside 320 of the semiconductor device 304, thus thinning the fluid boundary layer and enhancing heat transfer from the semiconductor device 304 to the fluid. Thus, the shower plate 334 may alternatively be referred to as a vortex plate.

In some embodiments, the sidewalls of the plurality of openings 336 may be funnel shaped such that a cross-section of an upper opening facing the top portion of the manifold 306 is greater than a cross-section of a lower opening facing the semiconductor device 304. The funnel shaped sidewalls accelerate the flow of fluid as the fluid flows through the openings 336 which focuses fluid streams towards certain areas of the backside 320 of the semiconductor device 304.

Overall performance of the device package 301 is improved due to the enhanced cooling properties provided by the megasonic transducer 314 optionally in combination with the helicoidal ribs and/or funnel shaped sidewalls. For example, the megasonic vibrations generated by the megasonic transducer 314 may be transferred towards the backside 320 of the semiconductor device 304 through turbulent fluid, in the form of a vortex, induced by helicoidal ribs of the openings 336. Furthermore, the pressure at which the turbulent fluid and megasonic vibrations are projected towards the backside 320 of the semiconductor device 304 may be increased by the funnel shaped sidewalls which increase the rate of flow at which fluid passes through the openings 336 and across the backside 320 of the semiconductor device 304. The megasonic transducer 314 may be attached to the manifold 306 by any suitable method, e.g., by use of fasteners, an adhesive, or through direct bonding of the surfaces without the use of an intervening adhesive.

Here, the megasonic transducer 314 is attached to the manifold 306 without the use of an intervening adhesive material, e.g., the megasonic transducer 314 may be directly bonded to the manifold 306 such that the megasonic transducer 314 and the manifold 306 are in direct contact. In some embodiments, the megasonic transducer 314 is attached to the manifold 306 using a direct dielectric bonding process. In other embodiments, the megasonic transducer 314 is attached to the manifold 306 using a hybrid of direct dielectric bonds and direct metal bonds formed therebetween. For example, in some embodiments, one or both of the manifold 306 and the manifold-facing side of the megasonic transducer 314 comprise a dielectric material layer, e.g., a first dielectric material layer and a second dielectric material layer respectively and the megasonic transducer 314 is directly bonded to the manifold 306 through bonds formed between the dielectric material layers. In some embodiments, the megasonic transducer 314 is directly bonded to the manifold 306 using a hybrid bonding technique, where bonds are formed between the dielectric material layers and between metal features, such as between first metal pads and second metal pads, disposed in the dielectric material layers.

Suitable dielectrics that may be used as the dielectric material layers include silicon oxides, silicon nitrides, silicon oxynitrides, silicon carbon nitrides, metal-oxides, metal-nitrides, silicon carbide, silicon oxycarbides, silicon oxycarbonitride, silicon carbonitride, diamond-like carbon (DLC), or combinations thereof. In some embodiments, one or both of the dielectric material layers are formed of an inorganic dielectric material, e.g., a dielectric material substantially free of organic polymers. Typically, one or both of the dielectric layers are deposited to a thickness greater than the thickness of a native oxide, such as about 1 nanometer (nm) or more, 5 nm or more, 10 nm or more, 50 nm or more, 100 nm or more, or 100 nm or more. In some embodiments, the one or both of the layers are deposited to a thickness of 300 nm or less, such as 100 nm or less, 100 nm or less, or 50 nm or less.

In some embodiments, the shower plate 334 may be formed from non-crystalline silicon materials, such as a bulk substrate material comprising metal, metal alloys, ceramics, composite materials suitable for the bonding. For example, the shower plate 334 may be formed from a bulk material selected from the group comprising copper, aluminum, copper alloys (e.g., copper molybdenum alloys and copper tungsten alloys), iron-cobalt nickel alloys (e.g., Kovar® from Magellan Industrial Trading Co., Inc. of South Norwalk Connecticut United States of America), iron-cobalt nickel silver alloys, iron-nickel alloys (e.g., Invar® superalloys from Magellan), iron-nickel silicon alloys, aluminum silicon carbides, aluminum-silicon alloys, beryllium, beryllium oxides, beryllium, and beryllium oxide composites, aluminum-graphite fibers, copper-graphite fibers, metal diamond composite materials (e.g., aluminum diamond composites and silver-diamond composites), metal oxides, metal nitrides, and combinations thereof. The non-silicon substrate materials may be prepared for bonding and may or may not include a dielectric material layer deposited on the device-facing side to form a bonding surface.

The package cover 308 generally comprises one or more vertical or sloped sidewall portions and a lateral portion that spans and connects the sidewall portions. The sidewall portions extend upwardly from a peripheral surface of the package substrate 302 to surround the integrated cooling assembly 303 disposed thereon. The lateral portion is disposed over the integrated cooling assembly 303 and is typically spaced apart from the integrated cooling assembly 303 by a gap corresponding to the thickness of a an encapsulant material, which may be provided therebetween. Coolant fluid is circulated through the coolant chamber volume 310 through the inlet opening and the outlet opening formed through the lateral portion. In each of the embodiments described herein, coolant lines 940 (FIG. 9) may be attached to the device package 301 by use of connector features formed in the package cover 308, such as threads formed in the sidewalls of the inlet opening and the outlet opening.

Typically, the package cover 308 is formed of semi-rigid or rigid material so that at least a portion of the downward force exerted on the package cover 308 by a mounting frame is transferred to the supporting surface of the package substrate 302 and not transferred to the manifold 306 and the semiconductor device 304 therebelow. In some embodiments, the package cover 308 is formed of a thermally conductive metal, such as aluminum or copper. In some embodiments, the package cover 308 functions as a heat spreader that redistributes heat from one or more electronic components within a multi-component device package, such as described below.

Typically, the top portion of the manifold may be taken to be a portion to which the megasonic transducer 314 is attached. For example, the top portion of the manifold may be a sheet of manifold material separated from the backside 320 of the semiconductor device 304 by molding material. In such embodiments, the molding material disposed between the top portion of the manifold and the backside 320 of the semiconductor device 304, in combination with the top portion of the manifold itself, may act as the waveguide to guide sonic energy generated by the megasonic transducer 314 towards the backside 320 of the semiconductor device 304. In other embodiments, the top portion of the manifold may include sidewalls which extend downwardly towards the semiconductor device 304. The sidewalls may be attached directly to the backside of the semiconductor device, in which case the sidewalls act as the waveguide. Alternatively, molding material may be disposed between the sidewalls and the backside 320 of the semiconductor device 304, in which case the sidewalls and the attached molding material collectively act as the waveguide. As discussed above, the shower plate 334 may be attached to, and supported by, the sidewalls of the top portion of the manifold. Alternatively, in embodiments where molding material is disposed between the top portion of the manifold and the semiconductor device 304, the shower plate 334 may be attached to, and supported by, the molding material.

The term “sonic” is taken to mean a sound wave (e.g., sonic energy) which produces cycles of compression and rarefaction in density and pressure. It will therefore be understood that the term “megasonic” refers to sonic (sound) waves having a frequency (cycle) range that may reasonably be represented with the metric prefix “Mega” (e.g., MHz), which denotes a factor of one million (e.g., 10⁶ or 1000000). The megasonic transducer of the present disclosure may generate megasonic vibrations, associated with transmitted sonic energy, in the frequency range of about 200 k Hz (e.g., 0.2 MHz) to about 5 MHz (e.g., 0.195 MHz, 0.350 MHz, 4.2 MHZ, and 5.2 MHz), such as a frequency range of about 0.5 MHz to about 3 MHZ.

In alternative embodiments, other types of transducer may be used in addition to or in place of the megasonic transducer. Such transducers may operate in different frequency ranges to the megasonic transducer. For example, an ultrasonic transducer may be used to generate ultrasonic vibrations in a frequency range below the frequency range of operation of the megasonic transducer (e.g., a frequency range of about 20 kHz to about 200 kHz).

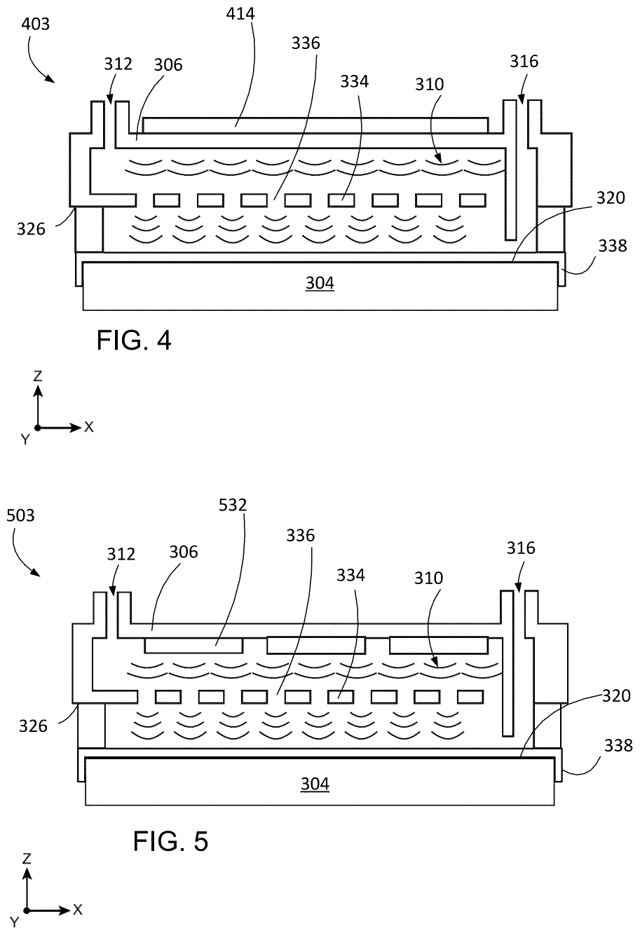

FIG. 4 is a schematic sectional view of integrated cooling assembly 403, according to another embodiment, that may be used in the device package 301. Here, the integrated cooling assembly 403 includes a semiconductor device 304 and a manifold 306 attached to the semiconductor device 304, such as described above in relation to FIG. 3, and a megasonic transducer 414 positioned to direct megasonic energy towards the semiconductor device 304. As shown, the megasonic transducer 414 is attached to the second side of the top portion of the manifold such that the megasonic transducer 414 is disposed outside of the coolant chamber volume 310. The megasonic transducer 414 may be attached to the second side using the same techniques as described above in relation to the megasonic transducer 314 of FIG. 3.

FIG. 5 is a schematic sectional view of integrated cooling assembly 503, according to another embodiment, that may be used in the device package 301.

Here, the integrated cooling assembly 503 includes a semiconductor device 304 and a manifold 306 attached to the semiconductor device, such as described above in relation to FIG. 3, and a megasonic transducer positioned to direct megasonic energy towards the semiconductor device 304. As shown, the megasonic transducer comprising plural elements 532 (e.g., segmented megasonic transducers). Each of the plural elements 532 may be an individual megasonic transducer having the same functionality as the megasonic transducer 314 of FIG. 3. Alternatively, the plural elements 532 may be sub-elements of the same megasonic transducer. In either arrangement, the plural elements 532 are positioned to transmit sonic energy towards the semiconductor device 304 (e.g., the backside 320 of the semiconductor device 304) through the coolant chamber volume 310 in the same manner as the megasonic transducer 314 of FIG. 3. Furthermore, each of the plural elements 532 may be independently controllable to transmit sonic energy at a different power or frequency and/or at different interval from one or more of the other plural elements. In embodiments illustrated by FIG. 4, the megasonic transducer comprises three elements 532 distributed evenly across the first side of the top portion of the manifold 306.

In such embodiments, each of the three elements may comprise an actuator that generates megasonic vibrations at different power or frequencies and/or intervals. For example, a first element of the three elements may generate megasonic vibrations at a frequency of 600 kHz for durations of 3 seconds, a second element of the three elements may generate megasonic vibrations at a frequency of 1 MHz for durations of 1 second, and a third element of the three elements may generate megasonic vibrations at a frequency of 2 MHz for a duration of 0.3 seconds. Similar different power densities may be applied to the megasonic transducer on demand to reduce hot spots within the integrated device 304. The waveguide directs the megasonic vibrations generated by the plural elements 532 through the coolant chamber volume 310 towards the semiconductor device 304. It will be understood that the integrated cooling assembly 503 of FIG. 5 may comprise any number of plural elements 532 distributed in various arrangements across the top portion of the manifold 306. In some embodiments, the plural elements 532 may be attached to the first side of the top portion of the manifold, as illustrated by FIG. 4. In other embodiments, the plural elements 532 may be attached to the second side of the top portion of the manifold.

Beneficially, providing plural elements 532, as described above, provides a means for generating focused cooling at specific regions of the backside of the semiconductor device 320 such that different zones of the integrated cooling assembly 503 have different power densities. Focused cooling at specific regions of the backside 320 of the semiconductor device 304 provides a means for preventing hot spots from occurring and/or for controlled cooling of hot spots if they do occur. Furthermore, the plural elements 532 provide increased redundancy. For example, if one of the plural elements 532 were to fail, sonic energy would still be transmitted towards the backside 320 of the semiconductor device 304 by the remaining operational elements 532.

FIG. 7 is a schematic sectional view of integrated cooling assembly 703, according to another embodiment, that may be used in the device package 301. Here, the integrated cooling assembly 703 includes a semiconductor device 304 and a manifold 706 attached to the semiconductor device 304, such as described above in relation to FIG. 3, and a megasonic transducer positioned to direct megasonic energy towards the semiconductor device 304. As shown, the manifold 706 does not include a shower plate 334 and the megasonic transducer comprising plural elements 532. Function of the plural elements 532 has been described above with reference to the integrated cooling assembly 503 of FIG. 5, and therefore this description will not be repeated for brevity.

As illustrated in FIG. 7, the coolant chamber volume 710 comprises only plural elements 532 (or a single continuous megasonic transducer) and fluid flowing into the coolant chamber volume 310 through the inlet opening 312 and out of the coolant chamber volume 310 through the outlet opening 316. A top portion of the manifold 706 illustrated in FIG. 7 comprises a first side facing towards the semiconductor device 304 and a second side opposite the first side, and the plural elements 532 are attached to the first side. In embodiments where the plural elements 532 of the integrated cooling assembly 703 are attached to the second side of the top portion of the manifold, the coolant chamber volume 310 comprises only fluid. As discussed above in relation to FIG. 3, the outlet opening 316 may comprise the outlet conduit extending into the coolant chamber volume 310, in which case the coolant chamber volume 310 may comprise only the outlet conduit, fluid and/or the megasonic transducer 314/plural elements 532.

The benefits provided by the megasonic transducer 314 and the plural elements 532, as discussed in relation to other integrated cooling assemblies above, apply equally to the integrated cooling assembly 703.

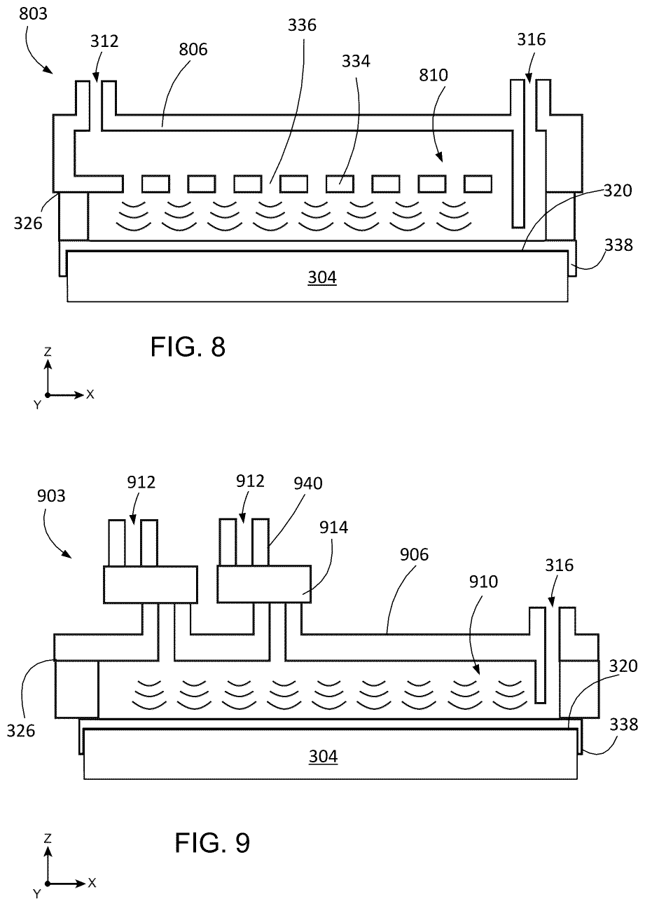

FIG. 8 is a schematic sectional view of integrated cooling assembly 803, according to another embodiment, that may be used in the device package 301. Here, the integrated cooling assembly 803 includes a device 304 and a manifold 806 attached to the semiconductor device 304, such as described above in relation to FIG. 3. As shown, the integrated cooling assembly 803 does not comprise a megasonic transducer. That is, the manifold 806 of the integrated cooling assembly 803 comprises a top portion, a waveguide, the shower plate 334, the inlet opening 312, and the outlet opening 316 only. In such embodiments, the backside 320 of the semiconductor device 304, the top portion of the manifold, and the waveguide collectively define a coolant chamber volume 810 therebetween, and the shower plate 334 is disposed between the top portion of the manifold and the backside 320 of the semiconductor device 304.

The benefits provided by the helicoidal ribs and/or funnel shaped sidewalls of the shower plate 334, as discussed in relation to other integrated cooling assemblies above, apply equally to the integrated cooling assembly 803.

FIG. 9 is a schematic sectional view of integrated cooling assembly 903, according to another embodiment, that may be used in the device package 301. Here, the integrated cooling assembly 903 includes a semiconductor device 304 and a manifold 906 attached to the semiconductor device 304, such as described above in relation to FIG. 3, and a megasonic transducer 914 positioned to direct megasonic energy towards the semiconductor device 304. As shown, the integrated cooling assembly 903 further comprises a coolant line 940 attached to the manifold 906. In a similar manner to the integrated cooling assembly 303 of FIG. 3, the manifold 906 comprises a top portion and a waveguide extending downwardly from the top portion to the backside 320 of the semiconductor device 304 thus defining a coolant chamber volume 910 therebetween. The top portion of the manifold 906 illustrated in FIG. 9 comprises a first side facing towards the semiconductor device 304 and a second side opposite the first side. Here, the coolant line 940 is positioned outside the coolant chamber volume 910 and is connected to the manifold 906 at a coolant line connection on the second side of the top portion of the manifold. The coolant line 940 may be attached to the manifold 906 by use of a connector feature, such as threads formed in the sidewalls of the coolant line connection. Fluid may flow into the coolant line 940 through an inlet opening 912, into the coolant chamber volume 910, and out of the outlet opening 316. In some embodiments, the coolant line 940 is flexible tubing which reduces the likelihood of failure due to cracking or splitting of the coolant line 940 during movement.

As illustrated in FIG. 9, a megasonic transducer 914 may be connected along the coolant line 940 between the inlet opening 912 and the coolant line connection. The megasonic transducer 914 may be coupled to the coolant line 940 such that fluid passes through the megasonic transducer 914 as it flows along the coolant line 940. Megasonic vibrations generated by the megasonic transducer 914 may cause sonic energy to be transmitted through the fluid along the coolant line 940, through the coolant chamber volume 310, and towards the backside 320 of the semiconductor device 304.

The coolant line connection may comprise side walls having helicoidal ribs which generate a vortex in the fluid as the fluid flows from the coolant line 940 into the coolant chamber volume 910. Furthermore, the coolant line connection may be funnel shaped to accelerate the flow of fluid as the fluid flows from the coolant line 940 into the coolant chamber volume 910. The benefits provided by the helicoidal ribs and/or funnel shaped sidewalls of the shower plate 334, as discussed in relation to the shower plates above, apply equally to the coolant line 940 of the integrated cooling assembly 903.

FIG. 10 is a schematic sectional view of device package 1001, according to another embodiment, that may be used with the system panel 100. Here, the device package 1001 includes an integrated cooling assembly 1003 comprising a semiconductor device 304 and a megasonic transducer 314 positioned to direct megasonic energy towards the semiconductor device 304. As shown, the integrated cooling assembly 1003 comprises a manifold and a package cover which are integrated as a manifold-package cover 1006. The manifold-package cover 1006 is attached to the semiconductor device 304. The manifold-package cover 1006 provides the same functionality as any of the above discussed manifolds in combination with the above discussed package cover 308. Here, fluid is delivered to a coolant chamber volume 310 through inlet opening 312 and outlet opening 316 of the manifold-package cover 1006. A top portion of the manifold-package cover comprises a first side facing the semiconductor device 304 and a second side opposite the first side. In embodiments illustrated by FIG. 10, the megasonic transducer 314 is attached to the first side of the top portion of the manifold-package cover 1006. It will be understood that alternative megasonic transducer arrangement may be provided in the integrated cooling assembly 1003 of FIG. 10, as discussed in embodiments above and below.

As illustrated in FIG. 10, the device package 1001 may further comprise an encapsulant material 1002 that surrounds an interface between the semiconductor device 304 and the package substrate 302 (and optionally the manifold-package cover 1006). The encapsulant material 1002 may comprise a polymer or epoxy material that extends upwardly from the package substrate 302 to encapsulate and/or surround at least a portion of the semiconductor device 304. In some embodiments, encapsulant material 1002 is formed from a compound (e.g., a thermoset resin, that when polymerized, forms a hermetic seal between the package cover 308 and the semiconductor device 304). In some embodiments, the encapsulant material 1002 comprises a particulate composite material, the particulate elements having been compounded with the resin to mechanically reinforce the cure resin and also reduce the CTE of the cured resin.

Beneficially, the encapsulant material 1002 provides mechanical support that improves system reliability and extends the useful lifetime of the device package 1001. For example, the encapsulant material 1002 may reduce mechanical stresses that can weaken interfacial bonds and/or electrical connections between electrical components of the device package 1001, such as stresses caused by vibrations, mechanical and thermal shocks, and/or fatigue caused by repeated thermal cycles. It will be understood that the encapsulant material 1002 may be used with any of the integrated cooling assemblies discussed above and below.

FIG. 11 is a schematic sectional view of device package 1101, according to another embodiment, that may be used with the system panel 100. Here, the device package 1101 includes an integrated cooling assembly 1103 comprising a device 1104 and a manifold 1106 attached to the device 1104, such as described above in relation to FIG. 3, and a megasonic transducer 1114 positioned to direct megasonic energy towards the device 1104. As shown, the megasonic transducer 1114 comprises a portion spaced apart from a top portion of the manifold 1106 to define a fluid cavity. The megasonic transducer 1114 of embodiments according to FIG. 11 may be connected to the top portion of the manifold by sidewalls with the fluid cavity defined therebetween. The megasonic transducer 1114 may comprise an opening 1122 disposed therethrough. The opening 1122 may replace the inlet opening 312 described above in relation to the integrated cooling assembly 303. The opening 1122 may be in fluid communication with the coolant chamber volume 310 through one or more openings 1124 in the top portion of the manifold such that fluid flows between the fluid cavity and the coolant chamber volume 310. An example flow path of fluid through the fluid cavity and the coolant chamber volume 310 may be as follows:
1. fluid enters the fluid cavity through the opening 1122;
2. fluid flows from the fluid cavity to the coolant chamber volume 310 through the one or more openings 1124 of the top portion of the manifold;
3. fluid flows across the backside of the device 1104 and absorbs heat generated by the device 1104;
4a. in embodiments where the manifold 1106 comprises the outlet conduit, the fluid flows into the opening of the outlet conduit and exits the coolant chamber volume 310 via the outlet opening 316;
4b. in embodiments where the manifold 1106 does not comprise the outlet conduit, the fluid flows back through the coolant chamber volume 310 via the one or more openings 1124 and exits the coolant chamber volume 310 via the outlet opening 316.

In some embodiments, the one or more openings 1124 of the top portion of the manifold 1106 are defined by sidewalls comprising helicoid ribs 1326, as discussed above in relation to the shower plate 334 illustrated in FIG. 3. Furthermore, the one or more openings may be defined by funnel shaped sidewalls having the same benefits as the funnel shaped sidewalls discussed above in relation to the shower plate 334 illustrated in FIG. 3.

The manifold 1106 may be attached to the package substrate 302 using molding material 1102 (e.g., the same or similar type of molding material as discussed above).

As illustrated in FIG. 11, the device 1104 is a three-dimensional integrated circuit (3DIC) device comprising the semiconductor device 304 (e.g., a processor) and one or more second devices 1105 (e.g., memory, bonded to the device 304). In other embodiments, the device 1104 may comprises a plurality of chiplets or an interposer having a plurality of devices disposed thereon, e.g., a 2.5 dimensional integrated circuit (2.5DIC). Here, the backside of the device 1104 further comprises a corrosion protective layer 1138 formed over the second devices 1105 and exposed portions of the device 1104. The corrosion protective layer 1138 may have the same functionality, arrangement, and benefits as the corrosion protective layer 338 discussed above with reference to FIG. 3.

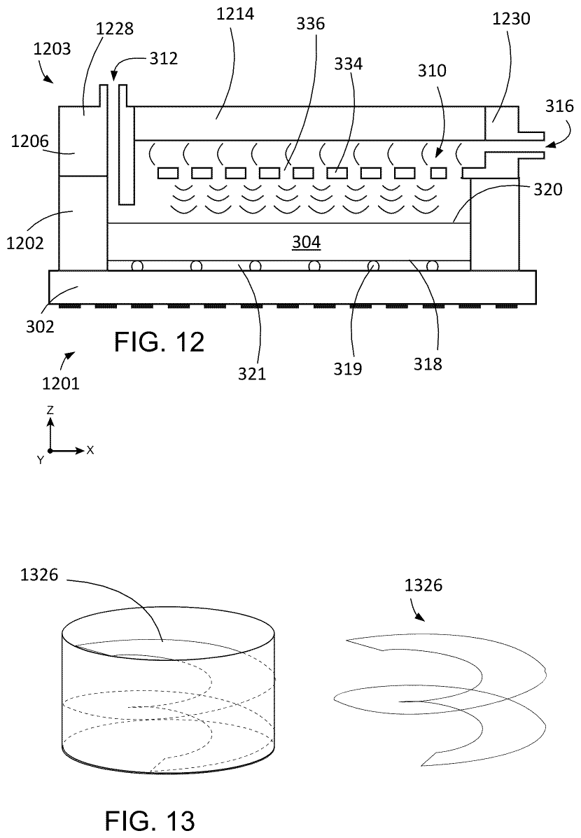

FIG. 12 is a schematic sectional view of device package 1201, according to another embodiment, that may be used with the system panel 100. Here, the device package 1201 includes an integrated cooling assembly 1203 comprising a semiconductor device 304 and a manifold 1206 attached to the semiconductor device 304, such as described above in relation to FIG. 3, and a megasonic transducer 1214 positioned to direct megasonic energy towards the device. As shown, the manifold 1206 comprises a first portion 1228 and a second portion 1230 disposed above the semiconductor device 304 at opposite sides of the manifold 1206 with the (continuous) megasonic transducer 1214 disposed laterally therebetween. The first portion 1228 and the second portion 1230 may be separate portions with no direct connection therebetween. For example, the first portion 1228 may be connected to a first side of the megasonic transducer 1214 (e.g., the left-hand end in FIG. 12) and the second portion 1230 may be connected to a second side of the megasonic transducer 1214 (e.g., the right-hand end in FIG. 12). In a similar manner to the manifold 1106 of FIG. 11, the first portion 1228 and the second portion 1230 may be connected to the package substrate 302 with the semiconductor device 304 disposed therebetween. The continuous megasonic transducer may extend continuously between the first portion 1228 and the second portion 1230 and may extend across the same footprint as the backside of the semiconductor device 320.

The inlet opening 312 may be disposed in the first portion 1228 of the manifold 1206 and the outlet opening 316 may be disposed in the second portion 1230 of the manifold 1206. The first portion 1228 and the second portion 1230 may each comprise a first side facing away from the semiconductor device 304, which is external to the coolant chamber volume 310, and a lateral side laterally adjacent to the first side which is also external to the coolant chamber volume 310. In embodiments illustrated by FIG. 12, the lateral side of the first portion 1228 is on the left-hand side of the integrated cooling assembly 1203 and the lateral side of the second portion 1230 is on the right-hand side of the integrated cooling assembly 1203. As illustrated in FIG. 12, the inlet opening 312 may be disposed on the first side of the first portion 1228 and may comprise an inlet conduit connected to the inlet opening 312 which extends into the coolant chamber volume 310 towards the backside of the semiconductor device 320. Furthermore, the outlet opening 316 may be disposed on the lateral side of the second portion 1230. It will be understood that arrangements of the first portion 1228 and the second portion 1230 may be reversed or match. As with the integrated cooling assembly 1103, the manifold 1206 may be attached to the package substrate 302 using molding material 1202 (e.g., the same or similar type of molding material as discussed above).

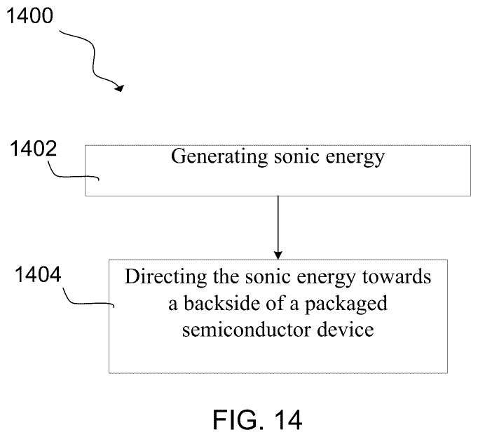

FIG. 14 shows a method 1400 of cooling a packaged semiconductor device. At block 1402, the method 1400 includes generating, by a megasonic transducer, sonic energy. The megasonic transducer used to generate sonic energy may be a megasonic transducer having the same constructions and/or functionality as any of the megasonic transducer described above.

At block 1404, the method 1400 includes transmitting, by the megasonic transducer, the sonic energy through a fluid towards a backside of the packaged semiconductor device. The means by which sonic energy is generated and transmitted through the fluid may be means according to any of the integrated cooling assemblies described above.

The method described above advantageously provides for device packages having improved performance due to the enhanced cooling properties provided by the megasonic transducer optionally in combination with helicoidal ribs and/or funnel shaped sidewalls, as described above.

The embodiments discussed above are intended to be illustrative and not limiting. One skilled in the art would appreciate that individual aspects of the device packages and methods discussed herein may be omitted, modified, combined, and/or rearranged without departing from the scope of the disclosure. Only the claims that follow are meant to set bounds as to what the present disclosure includes.

1. A device package comprising:
an integrated cooling assembly comprising a semiconductor device, a manifold attached to the semiconductor device, and a sonic transducer attached to the manifold, wherein:
the manifold comprises a top portion and a waveguide extending downwardly from the top portion;
the sonic transducer is attached to the top portion; and
the top portion, the waveguide, and a backside of the semiconductor device collectively define a coolant chamber volume therebetween.

2. The device package of claim 1, wherein the top portion of the manifold comprises:
a package cover, the package cover having an inlet opening and an outlet opening disposed therethrough, and wherein:
the coolant chamber volume is in fluid communication with the inlet opening and the outlet opening.

3. The device package of claim 1, wherein the manifold is attached to the semiconductor device with a compliant adhesive layer.

4. The device package of claim 1, wherein the manifold comprises a polymer material.

5. The device package of claim 2, wherein:
the top portion of the manifold comprises a first side facing towards the semiconductor device and a second side opposite the first side, and
the sonic transducer is attached to the first side.

6. The device package of claim 5, wherein the sonic transducer is disposed in the coolant chamber volume.

7. The device package of claim 2, wherein:
the top portion of the manifold comprises a first side facing towards the semiconductor device and a second side opposite the first side, and
the sonic transducer is attached to the second side.

8. The device package of claim 7, wherein:
a portion of the sonic transducer is spaced apart from the top portion of the manifold to define a fluid cavity; and
the sonic transducer has an opening disposed therethrough, and wherein the opening is in fluid communication with the coolant chamber volume through one or more openings in the top portion of the manifold.

9. The device package of claim 8, wherein sidewalls defining the one or more openings in the top portion of the manifold comprise helicoid ribs.

10. The device package of claim 2, wherein:
the manifold comprises a first portion and a second portion disposed above the semiconductor device at opposite sides of the manifold, and
the sonic transducer is a continuous transducer disposed laterally between the first and second portions of the manifold.

11. The device package of claim 10, wherein:
the inlet opening is disposed in the first portion of the manifold, and
the outlet opening is disposed in the second portion of the manifold.

12. The device package of claim 1, wherein the sonic transducer comprises plural elements each positioned to transmit sonic energy towards the semiconductor device through the coolant chamber volume.

13. The device package of claim 12, wherein each of the plural elements of the sonic transducer are independently controllable to transmit sonic energy at a different frequency and/or at different interval from one or more of the other plural elements.

14. The device package of claim 2, wherein the manifold comprises a shower plate disposed inside the coolant chamber volume between the top portion of the manifold and the semiconductor device, wherein the shower plate has a plurality of openings disposed therethrough.

15. The device package of claim 14, wherein sidewalls that define one or more of the plurality of openings of the shower plate comprise helicoid ribs.

16. The device package of claim 14, wherein the shower plate is formed of metal.

17. The device package of claim 1, wherein the sonic transducer is configured to transmit sonic energy at a frequency from about 200 kHz to about 5 MHz.

18. The device package of claim 1, wherein the sonic transducer comprises an actuator that generates sonic vibrations and the waveguide directs the sonic vibrations through the coolant chamber volume towards the semiconductor device.

19. The device package of any of claim 1, wherein the integrated cooling assembly comprises a corrosion protective layer disposed on the backside of the semiconductor device.

20. The device package of claim 1, further comprising a package substrate, wherein:
the manifold is disposed on the package substrate, and
the semiconductor device is attached to the package substrate.

21.-57. (canceled)

58. The device package of claim 1, wherein the manifold is attached to the semiconductor device by direct hybrid bonds.

59. The device package of claim 1, wherein the manifold is attached to the semiconductor device by direct dielectric bonds.
